(19) United States
(12) Patent Application Publication
(10) Pub. No.: US 2012/0104346 A1
(43) Pub. Date: May 3, 2012

(54) SEMICONDUCTOR DEVICE FOR PROVIDING HEAT MANAGEMENT

(76) Inventors: Wei Yi, Mountain View, CA (US); Matthew D. Pickett, San Francisco, CA (US); Gilberto Medeiros Ribeiro, Menlo Park, CA (US)

(21) Appl. No.: 12/916,414

(22) Filed: Oct. 29, 2010

(51) Int. Cl. H01L 45/00; B82Y 99/00

(52) U.S. Cl. 257/4; 257/E45.003; 977/943

(57) ABSTRACT

A semiconductor device for providing heat management may include a first electrode with low metal thermal conductivity and a second electrode with low metal thermal conductivity. A metal oxide structure which includes a transition metal oxide (TMO) may be electrically coupled to the first electrode and second electrode and the metal oxide structure may be disposed between the first electrode and second electrode. An electrically insulating sheath with low thermal conductivity may surround the metal oxide structure.

### BACKGROUND

As the use of digital data increases, the demand for faster, smaller, and more efficient memory structures increases. One type of memory structure is a crossbar memory array. A crossbar memory array may include a first set of conductive lines which intersect a second set of parallel conductive lines. Programmable memory elements configured to store digital data can be placed at intersections between the first set of lines and second set of lines.

One type of memory element which can be used is a memristive memory element. A memristive memory element can change the state of its resistance in response to an applied electrical condition such as a voltage or an electric current. The resistive state of a memristive memory element can be used to store digital data. For example, a high resistance state can represent a digital ‘0’ and a low resistance state can represent a digital ‘1’.

### BRIEF DESCRIPTION OF THE DRAWINGS

FIG. 1 is an illustrative diagram showing a crossbar array in accordance with an example;

FIG. 2A is an illustrative diagram showing a current path through a target memory element in portion of a crossbar memory array in accordance with an example;

FIG. 2B is an illustrative diagram showing a current path through an unselected memory element in portion of a crossbar memory array in accordance with an example;

FIG. 3 is an illustrative graph showing electrical resistivity to temperature relationship of transition metal oxides (TMO) in accordance with an example;

FIG. 4A is an illustrative graph showing a current to voltage relationship of a transition metal oxide (TMO) Metal-“Insulator”-Metal (MIM) device in accordance with an example;

FIG. 4B is an illustrative diagram showing high-current-density (J) “filaments” in a high resistance state (HRS) of a transition metal oxide (TMO) Metal-“Insulator”-Metal (MIM) device in accordance with an example;

FIG. 4C is an illustrative diagram showing a metallic inclusions in a negative differential resistance (NDR) state of a transition metal oxide (TMO) Metal-“Insulator”-Metal (MIM) device in accordance with an example;

FIG. 4D is an illustrative diagram showing metallic shunt paths in a low resistance state (LRS) of a transition metal oxide (TMO) Metal-“Insulator”-Metal (MIM) device in accordance with an example;

FIG. 5A is an illustrative diagram showing an equivalent static thermal circuit on a transition metal oxide (TMO) Metal-“Insulator”-Metal (MIM) device in accordance with an example;

FIG. 5B is an illustrative diagram showing an equivalent static thermal circuit of a transition metal oxide (TMO) Metal-“Insulator”-Metal (MIM) device in accordance with an example;

FIG. 5C is an illustrative diagram showing an equivalent dynamic thermal circuit of a transition metal oxide (TMO) Metal-“Insulator”-Metal (MIM) device in accordance with an example;

FIG. 5D is an illustrative graph showing a power and temperature relationship to time of a dynamic thermal circuit of a transition metal oxide (TMO) Metal-“Insulator”-Metal (MIM) device in accordance with an example;

FIG. 6A is an illustrative graph showing a current to voltage relationship of a thermally insulating transition metal oxide (TMO) Metal-“Insulator”-Metal (MIM) device in accordance with an example;

FIG. 6B is an illustrative graph showing a current to voltage relationship of a thermally conductive transition metal oxide (TMO) Metal-“Insulator”-Metal (MIM) device in accordance with an example;

FIG. 7A is an illustrative diagram showing a transition metal oxide (TMO) Metal-“Insulator”-Metal (MIM) device in accordance with an example;

FIG. 7B is an illustrative diagram showing a transition metal oxide (TMO) Metal-“Insulator”-Metal (MIM) device in accordance with an example;

FIG. 7C is an illustrative diagram showing a memory element within a transition metal oxide (TMO) Metal-“Insulator”-Metal (MIM) device in accordance with an example; and

FIG. 7D is an illustrative diagram showing a memory element electrically coupled to a transition metal oxide (TMO) Metal-“Insulator”-Metal (MIM) device in accordance with an example.

### DETAILED DESCRIPTION

Alterations and further modifications of the illustrated features, and additional applications of the principles of the examples, which would occur to one skilled in the relevant art and having possession of this disclosure, are to be considered within the scope of the disclosure. The same reference numerals in different drawings represent the same element.

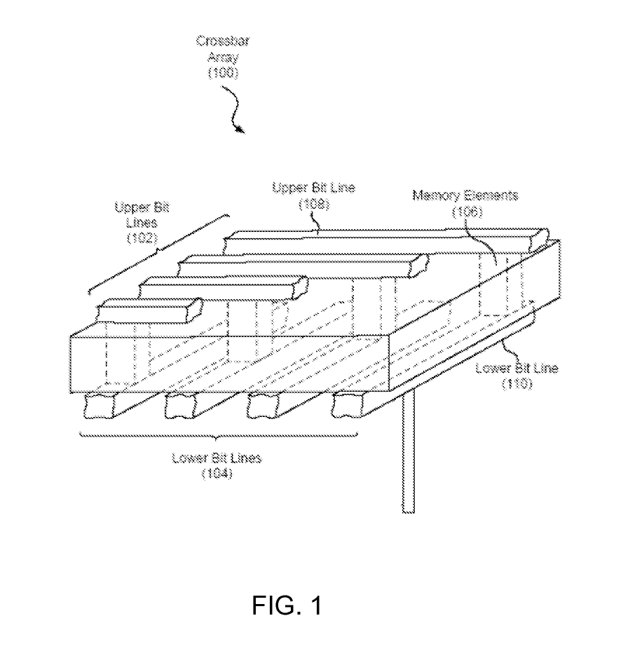

FIG. 1 illustrates a crossbar memory array 100 architecture. The crossbar memory array may include upper bit lines 102 (e.g., row lines), which may be generally in parallel. Additionally, the crossbar memory may include lower bit lines 104 (e.g., column lines) that may be generally perpendicular to, and intersects, the upper bit lines. Memory devices 106 may be formed at the intersections between a row line 108 and a column line 110.

A particular memory element within a crossbar array may be written to by applying half of a write voltage to one wire connected to the target memory element and the other half of the write voltage to the other wire connected to the target memory element. The target memory may be changed to the opposite state (e.g., a digital ‘0’ to a digital ‘1’, or a digital ‘1’ to a digital ‘0’) by reversing the polarity of the half of the write voltages. A half write voltage to both the row line and the column line applies the full write voltage to the target memory element while applying half of the write voltage to the other memory elements, called half-selected memory elements, on the row line and the column line. When half of the write voltage is applied to the half-selected memory elements, a current may be produced which can change the state of the half-selected memory elements from a high resistance digital ‘0’ state to a low resistance digital ‘1’ state, or vice versa.

In a read operation, the half voltage applied on each row or column line to the target memory element and the half-selected memory elements may be referred to as half of a read voltage. The read voltage may have a magnitude smaller than the write voltage. When half of the read voltage is applied to the half-selected memory elements, a current may be produced which adds to the current sensed by the reading circuitry used to sense the electric current from the target memory element.

Each half-selected memory element may contribute a small amount of unwanted current, called sneak current, to sensing circuitry used to sense the current flowing through the target memory element. To limit the amount of sneak current contributed by the half-selected memory elements, non-linear devices can be used to decrease resistance at full read voltage and increase resistance at half of the read voltage. Using devices with a higher degree of non-linearity allows a memory array with more memory elements along a particular wire line to be produced.

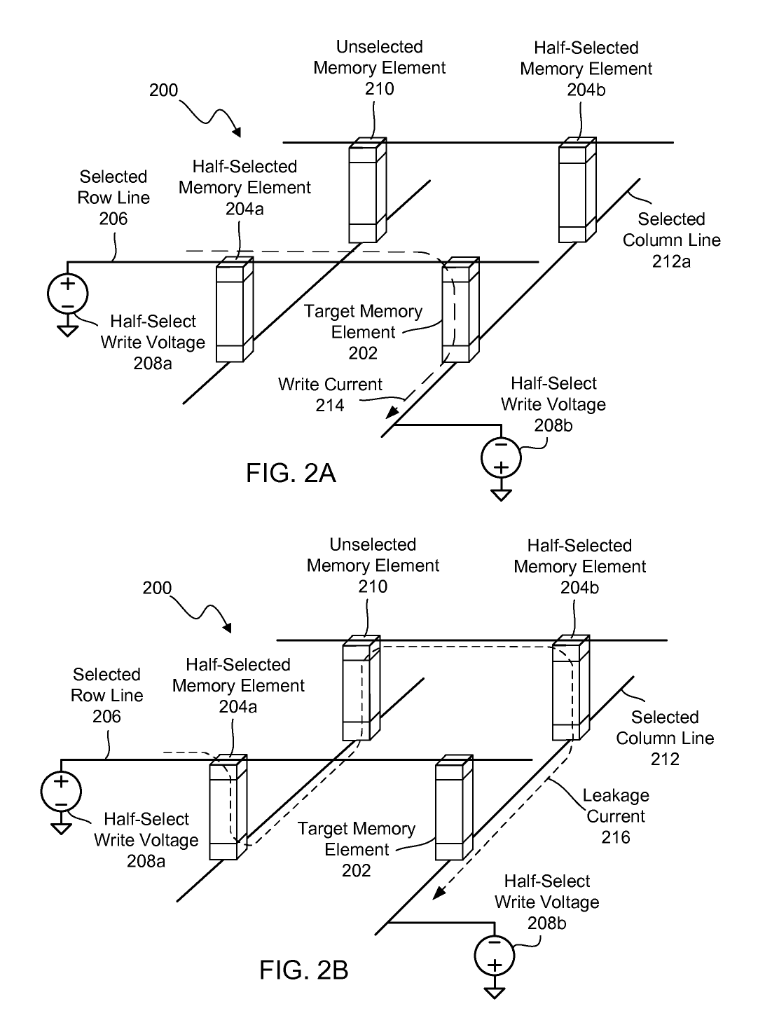

FIGS. 2A-2B illustrates a section of a crossbar array 200 with a write voltage applied during a write operation. To access a particular memory element, a voltage may be applied across that element. The memory element to be accessed may be referred to as the target memory element 202. To write or change the state of the target memory element, a half-select write voltage 208a may be applied to a selected row line 206 connected to the target memory element. With the half-select write voltage applied, each memory element 204a along the selected row line, including the target memory element may become half-selected. To fully select the target memory element, a half-select write voltage 208b may be applied to the selected column line 212 connected to the target memory element. With the half-select write voltage applied to the selected column line, the memory elements 204b along the selected column line may become half-selected, except for the target memory element which may become fully selected. The half-select write voltage applied to the column line may be the inverse polarity of the half-select write voltage applied to the selected row line. A voltage drop across the target memory element may result due to the sum of both half-select read voltages. With the full voltage applied across the target memory element 202, a write current 214 may flow through the selected row line 206, the target memory element, and the selected column line 212, as illustrated in FIG. 2A. The direction and the magnitude of the write current may be indicative of the state of the target memory element. In a read corresponding operation, sensing circuitry can be used to measure the value of the read current and determine whether the target memory element is storing a digital ‘1’ or a digital ‘0’.

When applying half-select write voltages to the row lines 206 and column lines 212, memory elements 204a and 204b along those lines may become half-selected. A leakage current or sneak current may flow through the half-selected memory elements as well. FIG. 2B illustrates a possible path of a sneak current 216. The value of the sneak current may be dependent on the current to voltage relationship of the memory elements. A large sneak current may change the state of half-selected memory elements in a write operation or interfere with the read current and make it difficult for the sensing circuitry to accurately determine the state of the target memory element 202 in a read operation. Using memory elements with a high non-linearity may reduce the value of the electric current contributed by each of the half-selected memory elements to the sneak current or other unselected devices 210. Memory elements with a high degree of non-linearity may contribute a relatively small amount to the sneak current allowing more memory elements to be placed along a particular line without creating large sneak current, thereby maintaining the state of half-selected memory elements in write operations and allowing the sensing circuitry to accurately determine the state of the target memory element in read operations.

Memristive memory element can be made by defect (e.g. oxygen vacancies) mediated resistive switching in transition metal oxides such as TiO₂, HfO₂, and VO₂. For passive crossbar memory array without a select/blocking device (transistor or diode) to block the unaddressed elements, crosstalk issues may be produced by the phenomenon of “half-select” current paths as described above.

Highly nonlinear current-voltage (I-V) characteristics observed in transition metal oxides can be used as embedded blocking device at each memristive memory cell to mitigate the issue of half-select current. Such nonlinear I-V can be a current-controlled (CC) negative differential resistance (NDR) induced by metal-insulation transition.

The metal-insulator transition occurs at certain temperature, while the steady state (for DC operation) and transient (for pulse operation) temperature of the active region in TMO based memristive device can be determined by heat generation balanced by heat leakage. Therefore, thermal engineering of a nanoscale memory cell can tune the CC-NDR characteristics, and obtain desired nonlinear I-V feature to block half-select current.

A memory element with a high degree of non-linearity may include a non-linear device in series with the memory element. The non-linear device may include a Metal-Insulator Transition (MIT) material. A MIT material may make transition from an insulator to a conductor under certain conditions such as temperature, pressure, or the application of electrical conditions such as a voltage or current which generates Joule heating, or combination of temperature, pressure, or electrically induced heat.

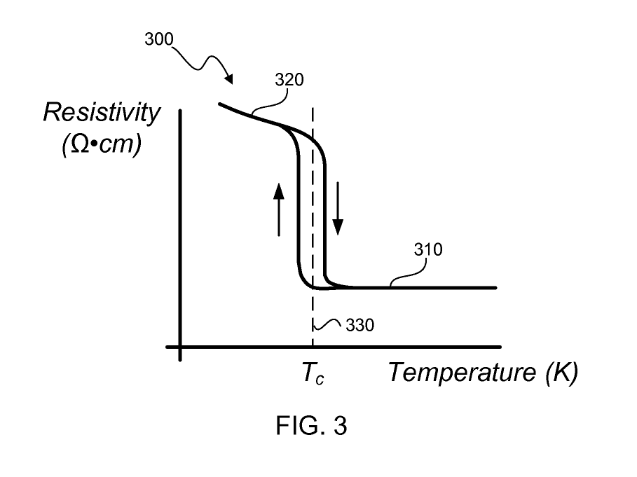

A MIT material may be an early transition metal oxide (TMO). A TMO may exhibit a first-order metal insulator phase transition at a specified temperature or narrow temperature range, illustrated in FIG. 3. Some TMOs can have a corresponding sharp transition in electrical resistivity (or conductivity) to temperature relationship 300. Some TMOs may have insulating or high resistance properties at lower temperatures 310 and may become conductive or have low resistance properties at higher temperatures 320, exhibiting a sharp transition from insulating to conductive at a specified temperature or temperature range. The TMO may make an accompanying structural transition from a rutile to a distorted variant at a transition temperature range. Some TMOs may have hysteresis in the conductivity characteristics at a transition temperature (T_{c}) 330.

An early transition metal for the TMO may include Vanadium (V), Titanium (Ti), Niobium (Nb), Tantalum (Ta), Manganese (Mn), Hafnium (Hf), Molybdenum (Mo), Tungsten (W), Chromium (Cr), Zirconium (Zr), Scandium (Sc), Yttrium (Y), Lanthanum (La), Rhenium (Re), or Technetium (Tc) thus a TMO may be an oxide that includes an early transition metal. A TMO may include vanadium oxide, titanium oxide, niobium oxide, tantalum, or manganese oxide. An early transition metal may include elements from the third group, fourth group, fifth group, sixth group, or seventh group on the periodic table, or combination of elements from these groups. An early transition metal may include binary, ternary, or quaternary alloys including one or more types of early transition metals.

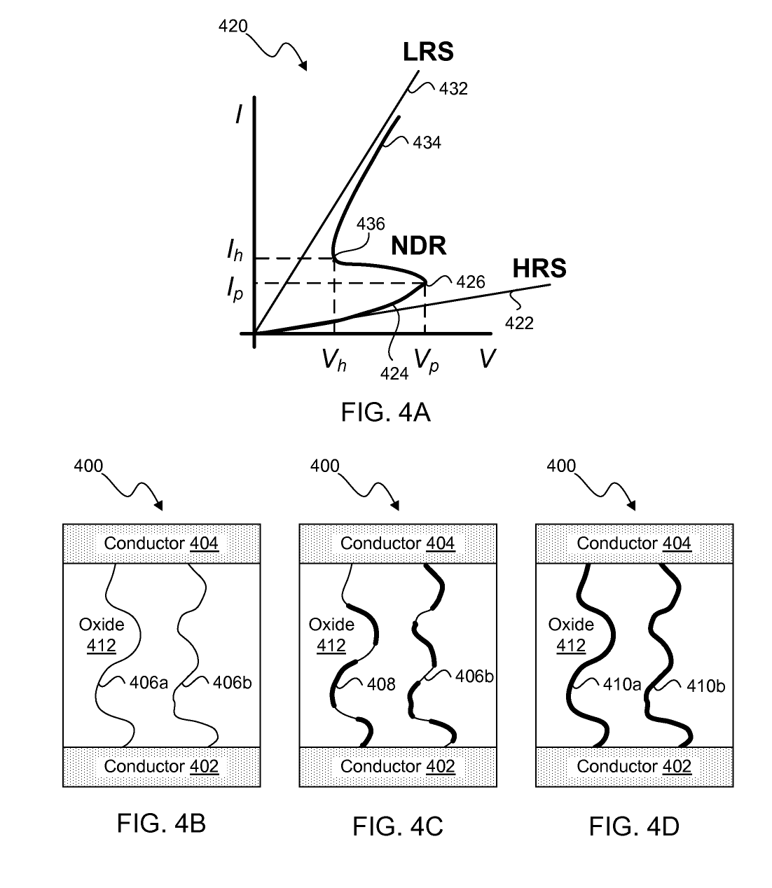

TMOs may be disposed between two conductive electrodes forming Metal-“Insulator”-Metal (MIM) sandwich devices or Metal-Oxide-Metal (MOM) devices. A MIM device or MOM device may exhibit an “S” shaped current controlled (CC) negative differential resistance (NDR) behavior for direct current (DC) or under low-frequency conditions, as indicated in FIG. 4A. The vertical axis represents electric current and the horizontal axis represents voltage. A device which exhibits NDR may experience a decrease in voltage at certain levels of increasing current creating an ‘S’ shaped curve in the current-to-voltage relationship. Some MIM or MOM devices may exhibit a pinched hysteresis in “S” shaped CC-NDR I-V characteristics, which can be described by the framework of memristive switching.

As illustrated in FIG. 4A, an “S” shaped CC-NDR MIM device may have three different states or phases, which include a high resistance state (HRS), a negative differential resistance (NDR), and a low resistance state (LRS). FIG. 4A illustrates a graph 420 of a “S” shaped NDR current-voltage relationship. A HRS 422 may represent the approximate slope of the current-voltage relationship of the CC-NDR MIM device at a low current state showing the device as having insulating properties or high resistance, and thus the device may act as an insulator. A LRS 432 may represent the approximate slope of the current-voltage relationship of the CC-NDR MIM device at a high current state showing the device as having conductive properties or low resistance, thus the device may act as a conductor. The NDR state may occur between the HRS and the LRS, where an increase in current results in a decrease in voltage after a specified minimum voltage. The HRS-NDR transition from the MIM device HRS 424 to the NDR region may occur at a first knee 426, a peak knee, or threshold voltage and threshold current referred to as a peak voltage (Vₚ) and a peak current (Iₚ), respectively. The NDR-HRS transition from the NDR region to the MIM device LRS 434 may occur at a second knee 436, a holding knee, or holding voltage (Vₕ) and holding current (Iₕ).

On a nanoscale, a nominally “uniform” TMO-based MIM device may have oxide stoichiometry or current density (J) that may be nonuniform. At low and no current states, the oxide 412 between a first conductor or first metal 402 and a second conductor or second metal 404 of a MIM device 400 may have high-current-density “filaments” or high-J “filaments” 406a and 406b, as illustrated in FIG. 4B. The high-J filaments may be “defective” regions with higher concentration of oxygen vacancies or other forms of defects or regions with higher conductivity than other parts of the oxide. At a current below the peak current (Iₚ) or a temperature below a transition temperature, the oxide may be in a HRS. The transition temperature may be the temperature at which a solid material changes from one crystal state to another.

A MIT can be initiated by the application of a current to the MIM device 400 utilizing the high-J filaments 406a, 406b. When an electric current is injected between two electrodes 402 and 404 coupled to the TMO or oxide 412, the current may locally heat the oxide above a transition temperature. The rise above the transition temperature may cause current filamentation to occur. Current filamentation may be an inhomogeneity in the current density distribution orthogonal to the direction of current flow. Current filamentation may create metallic inclusions 408 in the high-J filaments 406, as illustrated in FIG. 4C. At a current exceeding the peak current (Iₚ) but below the holding current (Iₕ), the oxide may be in a NDR phase. Alternatively, the current between Iₚ and Iₕ may be represented by temperature, so the oxide in the NDR phase may be within a transition temperature range. The transition temperature range may be with a few degrees Celsius (° C.) or may be within a degree C.

When the current exceeds the holding current (Iₕ) or the transition temperature, the oxide 412 may form metallic shunt paths 410 in the high-J filaments. The metallic shunts may be conductive in a LRS, as illustrated in FIG. 4D. The current filamentation may leads to current-controlled (CC) NDR. The injection of current in the MIM device can create local Joule heating through the defective regions of the oxide or the high-J filaments. The NDR characteristics can increase the non-linearity of the MIM device, which may be utilized in a memory element.

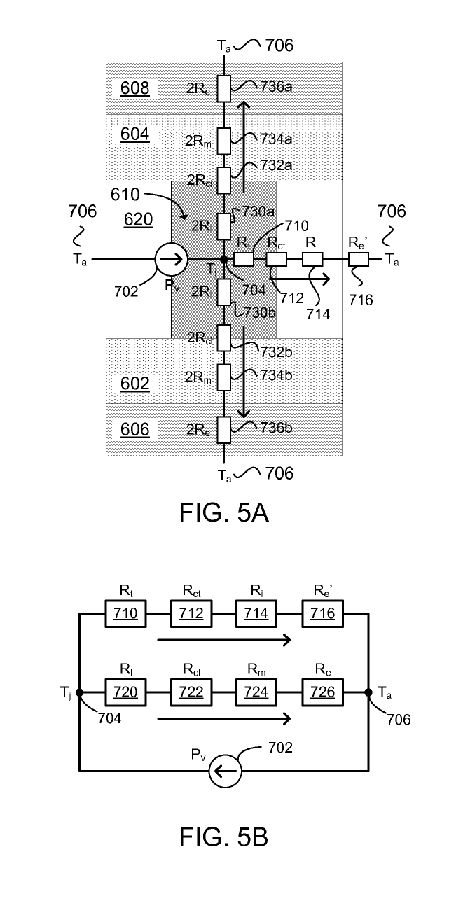

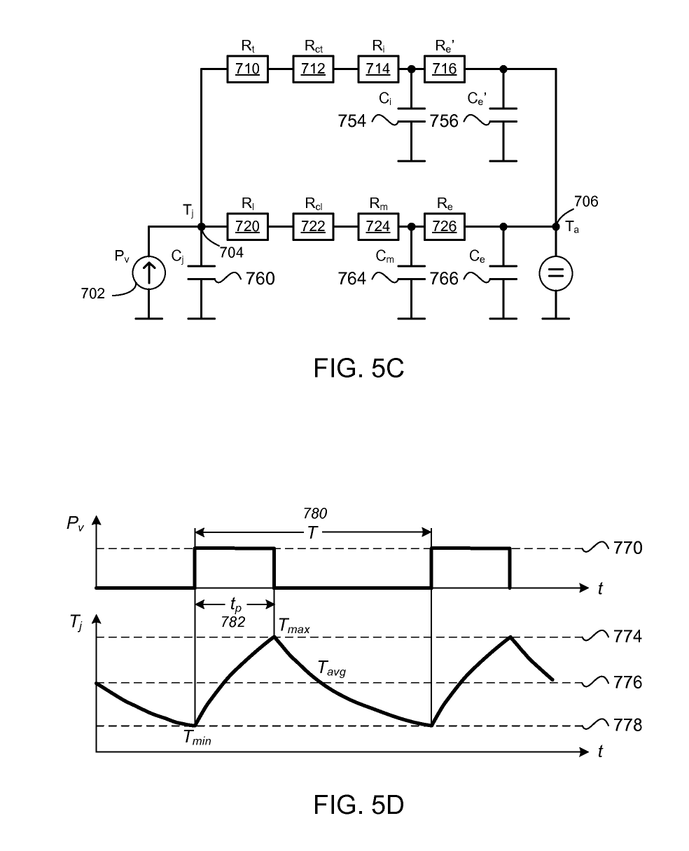

The conductivity of the TMO MIM device may be illustrated as a thermal circuit. FIG. 5A illustrates an example of a static thermal circuit overlaid on an illustrative diagram of TMO MIM device. The electrical current injected across electrodes 606 and 608 producing Joule heating can be symbolized by a thermal current source and may generate heat symbolized as a thermal source represented by power dissipation P_{V} 702 (in watt) occurring inside the active device or TMO structure 610 by Joule heating. For simplicity in illustrating the thermal circuit, the thermal resistance of the metal layer 606 and conductive layer 602 of the first electrode is equivalent to thermal resistance of the metal layer 608 and conductive layer 604 of the second electrode, respectively. For illustration, the first and second electrode/oxide interfaces and active device has thermal symmetry from above and below the Joule heating point Tj 704. In actual practice, a fabricated TMO MIM device may not have symmetry between electrodes, junctions, and within the active device. The thermal resistances Rₜₕ are represented by ohmic resistors. Thermal resistance can be defined as the temperature difference across a structure when a unit of heat energy flows through the structure in unit time. Thermal resistance may be the reciprocal of thermal conductance. The SI units for thermal resistance may be Kelvins per watt (K/W) or degrees Celsius per watt (° C./W).

As illustrated in FIGS. 5A and 5B, the “resistance” network for the equivalent static thermal circuit of the TMO MIM device may be formed by the following major components: R₁ 720 may represent the longitudinal thermal resistance within the active device 708 along the current flow direction. R₁ may be equivalent to 2R₁ 730a and 2R₁ 730b in parallel. Rₜ 710 may represent the transversal thermal resistance within the active device along the radial direction of the device column. R_{cl} 722 may represent the interfacial thermal resistance at the electrode/oxide interfaces at the contact area with first and second electrodes. Rd may be equivalent to 2R_{cl} 732a and 2R_{cl} 732b in parallel. Rₘ 724 may represent the bulk thermal resistance of the conductive layer electrode material. Rₘ may be equivalent to 2Rₘ 734a and 2Rₘ 734b in parallel. R_{ct} 712 may represent the interfacial thermal resistance at the oxide/insulator interfaces at the contact area with the surrounding dielectric insulator. Rᵢ 714 may represent the bulk thermal resistance of the dielectric insulator. Rₑ 726 and Rₑ′ 716 may represent the generalized thermal resistances of the nearby environment such as metal interconnects and package materials. Rₑ may be equivalent to 2Rₑ 736a and 2Rₑ 736b in parallel. The overall longitudinal thermal resistances (e.g., R₁, R_{cl}, Rₘ, and Rₑ) can be divided into two parallel branches, representing outbound heat flows upward and downward from the heating zone in the center Tⱼ 704. The ambient temperature may be represented by Tₐ 706 which can symbolized by a thermal voltage source. Simplifying the illustration, Tₐ may be represented as a thermal voltage level.

The region being heated by Joule heating may be symbolized by a hot point with temperature Tⱼ 704. The lump-summed longitudinal R_{L}, and transversal R_{T} thermal resistances are given in Equation 1 and Equation 2, respectively.

R_{L}=R₁+R_{cl}+Rₘ+Rₑ [Equation 1]

R_{T}=Rₜ+R_{ct}+Rᵢ+Rₑ′ [Equation 2]

The thermal current Pᵥ can be calculated from the “thermic Ohm's law” as Equation 3.

Tⱼ−Tₐ=P_{V}·Rₜₕ=P_{V}/(1/R_{L}+1/R_{T}) [Equation 3]

As illustrated in FIGS. 5C and 5D, an equivalent dynamic thermal circuit of the TMO MIM device may be formed by the thermal resistances of the static thermal circuit along with an addition equivalent thermal capacitors. The thermal behavior can change when dynamic phenomena are considered, such as applying a short electric pulse 782 at a specified power level 770. In such dynamic situations, the thermal capacity Cₜₕ can be a factor in Joule heating.

The thermal capacity Cₜₕ can be symbolized as a thermal capacitor in the thermal circuit and can be determined by the relevant material mass m (in g) and the specific heat cₚ (in W·s/g·K) given in Equation 4. Mass may be a product of the material volume V in cm³ and the density ρ in g/cm³).

Cₜₕ=cₚ·m=cₚ·ρ·V [Equation 4]

In order to calculate the temperature change, the quantity of heat Q (equivalent to the charge in electric circuit) generated on a thermal capacitor Cₜₕ may be calculated as given in Equation 5 where Δt is the duration of the electric pulse, thus ΔT (change in temperature) can be calculated as Equation 6.

Q=ΔT·Cₜₕ=P_{V}·Δt [Equation 5]

ΔT=P_{V}·Δt/Cₜₕ=P_{V}·Δt/(cₚ·ρ·V) [Equation 6]

Equation 6 illustrates that to increase the temperature change, reducing the relevant material volume V can be beneficial, since modifying cₚ and ρ can be limited. With the thermal capacitors added to a static thermal circuit, the dynamic thermal circuit may be illustrated by FIG. 5C with a power-temperature relationship over time illustrated by FIG. 5D. Cⱼ 760 may represent the thermal capacitance of the active device. Cₘ 764 may represent the thermal capacitance of the conductive layer electrode material. Cᵢ 754 may represent thermal capacitance of the dielectric insulator. Cₑ′ 756 and Cₑ′ 766 may represent the generalized thermal capacitance of the metal layer electrode material and the nearby environment such as metal interconnects and package materials.

The characteristic time constants of thermal response τ=Rₜₕ·Cₜₕ can be estimated for each component. For a pulse operation, the temperature response can be viewed as a voltage increase across an RₜₕCₜₕ section which is being fed by a current pulse generator. The increase in temperature can be written as Equation 7. The change in temperature may increase or generate to a maximum temperature Tₘₐₓ 774 and decay or dissipate to a minimum temperature Tₘᵢₙ 776 with a steady-state temperature or average temperature T_{avg} 778 for a periodic heating power P_{V} pulse with a duration of tₚ 782 and period of T 780.

ΔT=P_{V}·Rₜₕ·{1−exp[t/(Rₜₕ·Cₜₕ)]} [Equation 7]

From the static analysis, at a DC heating power P_{V}, the steady-state temperature build-up Tⱼ−Tₐ can be enhanced by increasing the overall thermal resistance formed by parallel branches of longitudinal and transverse R_{L} and R_{T} as given in Equation 3.

By engineering the thermal resistance components in the thermal circuit, local temperature within a TMO MIM device may be controlled, which can consequently control the MIT transition and the S-NDR I-V characteristics. Local temperature control and local Joule heating may be controlled by a combination of the resistance components illustrated by FIGS. 5A and 5B.

The thermal resistance of each component of the TMO MIM device may be determined by the relevant thickness d, the cross-sectional area A, and the thermal conductivity κ (in W/m·K) and is given by Equation 8.

Rₜₕ=d/κ·A [Equation 8]

As shown by Equation 8, the interfacial thermal resistances R_{cl} and R_{ct} can be inversely proportional to the contact areas in both the longitudinal and transversal direction. Therefore, by shrinking the contact areas to the metallic electrodes (junction area) and the surrounding dielectric insulator, a higher temperature change can occur in the active device at the same heating power.

From the dynamic analysis, at a short pulse heating power P_{V} with a duration of Δt or tₚ 782, the transient temperature build-up Tⱼ−Tₐ is enhanced by reducing the overall thermal capacity as given by Equation 6.

The thermal capacity of the device can be reduced by reducing the material volume and choosing materials with lower specific heat.

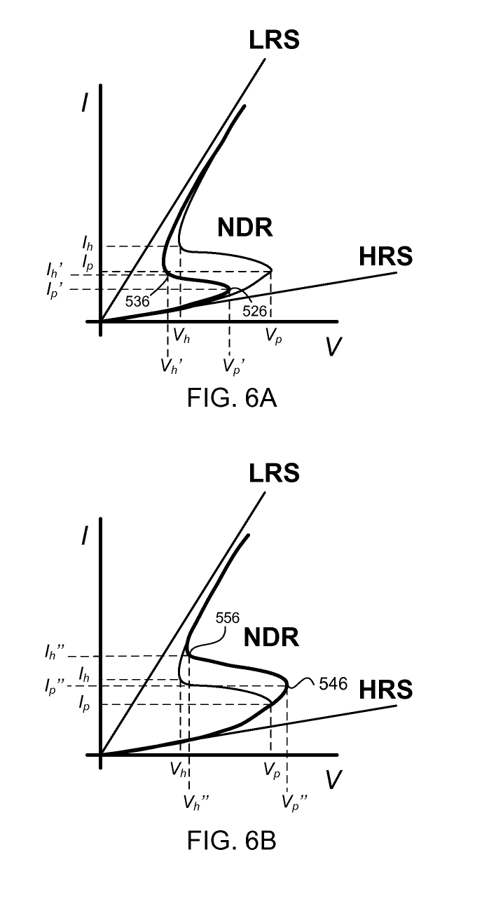

The TMO-based MIM device may be manufactured to provide nanoscale heat management or utilize local Joule heating. Nanoscale can include devices with geometries from one nanometer to hundreds of nanometer range (e.g. 1 nm to hundreds of nm). The “S”-NDR current-voltage characteristic parameters may be controlled or varied by the geometry, volume, and dimensions of the device structure, materials used, the manufacturing process, or a combination of the geometry, volume, and dimensions of the device structure, materials, and manufacturing process. As an example, enhanced local Joule heating and suppressed thermal leakage can promote the MIT to occur at lower characteristic peak voltage and current. The lower characteristic peak voltage and current can be realized by reducing the lateral sizes of the oxide junctions, reducing the thermal conductivity of the electrodes, reducing the thermal conductivity of the insulating material surrounding the TMO, or using a nanocomposite or multilayered oxides within a TMO layer to increase the interfacial thermal resistances between the electrodes in the MIM device. These methods by themselves or combined together may reduce the peak voltage (Vₚ), peak current (Iₚ), holding voltage (Vₕ), or holding current (Iₕ). FIG. 6A illustrates the S″-NDR current-voltage characteristics of a thermally insulating nanocomposite MIM device with small oxide junctions exhibiting reduced values for Vₚ′ and Iₚ′ at a reduced peak knee 526 and reduced values for Vₕ′ and Iₕ′ at a reduced holding knee 536.

Conversely, enlarging the lateral sizes of the oxide junctions, increasing the thermal conductivity of the electrodes, increasing the thermal conductivity of the insulating material surrounding the TMO, or using a single layer TMO structure between the electrodes in the MIM device may deter the MIT occurrence and increase the peak voltage (Vₚ), peak current (Iₚ), holding voltage (Vₕ), or holding current (Iₕ). FIG. 6B illustrates the S″-NDR current-voltage characteristics of a thermally conductive single layered TMO MIM device with relatively large oxide junctions exhibiting increased values for Vₚ″ and Iₚ″ at an enlarged peak knee 546 and increased values for Vₕ″ and Iₕ″ at an enlarged holding knee 556.

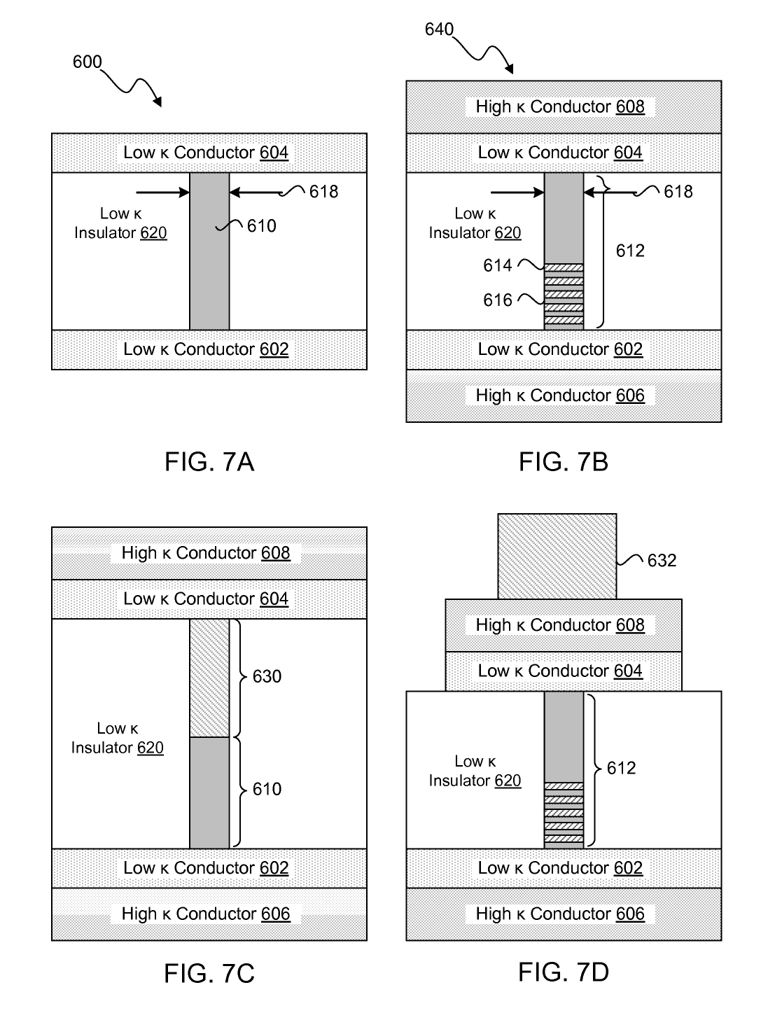

As illustrated in FIG. 7A, transition metal oxide (TMO) Metal-“Insulator”-Metal (MIM) device 600 may be a semiconductor device that includes a TMO structure 610 disposed between a first electrode 602 and a second electrode 604. An electrically insulating sheath 620 may surround the TMO structure or metal oxide structure. The TMO structure may be disposed between the first and second electrode and the electrically coupled to the first and second electrode. The metal oxide structure may exhibit first order metal-insulator phase transition (MIT) characteristics in a specified temperature range or transition temperature range. The metal oxide structure may exhibit current controlled (CC) negative differential resistance (NDR) current-voltage (I-V) characteristics at a specified temperature range or transition temperature range.

The first electrode 602 and second electrode 604 may have a low metal thermal conductivity (κ). The first electrode and second electrode may include low-κ metallic materials. The low-κ metallic materials may have a thermal conductivity (κ) less than 100 W/(m·K) for temperature range between 25° C. and 127° C. Low-K metallic materials may include refractory metal nitrides, refractory metal silicides, electrically doped polycrystalline semiconductors, or their combined intermediate phases. Nitrides that may be used for the electrodes may include complementary metal-oxide-semiconductor (CMOS) compatible transition metal nitrides such as TiN, Ta—N (in TaN or Ta₂N phases), WN₂, Nb—N (in various phases), or MoN. TiN may have a K approximately 29 W/(m·K) at 25° C. or approximately 24 W/(m·K) at 127° C. Silicides may include CMOS compatible metal silicides such as TiSi₂, TiSi, Ti₅Si₃, TaSi₂, WSi₂, NbSi₂, and V₃Si. Electrically doped polycrystalline semiconductors may include Silicon (Si) or Germanium (Ge) polycrystalline. Nitrides, silicides, and electrically doped polycrystalline semiconductors can have lower thermal conductivity than pure metals or metal alloys.

In another example illustrated in FIG. 7B, the first electrode and the second electrode may each include a metal layer 606 and 608 with high metal thermal conductivity disposed on a conductive layer 602 and 604 with low metal thermal conductivity. The conductive layers may be adjacent layers to the metal oxide structure or in closer proximity to the metal oxide structure than the metal layers. The conductive layer with the low metal thermal conductivity may provide thermal insulation for the metal oxide structure from the metal layer while still providing high electrical conductivity (low resistance) so the MIM device may use a lower current reach the transition temperature for the TMO structure. Using low thermal conductive materials may help trap the current generated heat in the MIM device. Local Joule heating may be provided with less current for a combined conductive layer and metal layer electrode MIM device than with electrodes made with metal layers. The metal layer may include CMOS compatible metals used for interconnects. The metal layer may include Platinum (Pt), Copper (Cu) with an inserted diffusion barrier, Aluminum (Al), Tungsten (W), Titanium (Ti), Molybdenum (Mo), Palladium (Pd), or Tantalum (Ta). The metal layer may have a thermal conductivity (κ) greater than 175 W/(m·K) for temperature range between 25° C. and 127° C.

A transition metal oxide (TMO) structure or a metal oxide structure including a transition metal oxide may include a single layer TMO 610 (FIG. 7A) or a nanostructure with a plurality of TMO layers 612 (FIG. 7B). The TMO may include Vanadium (W) oxide (VO₂), Titanium Magneli phase (Ti₄O₇), NbO₂, NiO, Ti₂O₃, MoO₃—TeO₂, or combination thereof. For example, VO₂ can have a first-order MIT with an associated structural change from distorted Rutile (monoclinic) to Rutile (tetragonal) at approximately 70° C.—a transition temperature. VO₂ can exhibit CC-NDR behavior and utilize a MIT mechanism at the transition temperature. In another example, Titanium Magneli phase (Ti₄O₇) can have a MIT and associated structural change at a transition temperature of approximately 150 K, which can be a cryogenic temperature.

The oxide junction may include the junction between the metal oxide structure 612 and an electrode 602 or 604 or the metal oxide layer and another oxide layer. The oxide junction area 618 may be the lateral cross-sectional area of the oxide junction. Reductions in the oxide junction area or lateral size in the metal oxide structure can decrease the interfacial thermal conductance of the metal oxide structure. The thermal conductivity for semiconductor nanowires may be much smaller than the bulk values for the same material due to phonon boundary scatterings and phonon confinement effect at the nanoscale dimensions. Nanowires can refer to wires with nanometer geometries and wires with geometries smaller than a nanometer. The oxide junction may have an elliptical, circular, rectangular, polygonal shape, or irregular shape. The oxide junction may have the same shape as the metal oxide structure. The lateral size of the oxide junctions can be determined by the lithography technology node. For example, the junction size can be approximately 50 nm and with nanofabrication techniques (e.g., nano-imprint lithography or e-beam lithography) junction sizes can be as small as approximately 10 nm. The junction size may be as small as a few nanometers or smaller.

As stated previously, a TMO structure or a metal oxide structure may include a nanostructure 612 with a plurality of TMO layers, as illustrated in FIG. 7B. The nanostructure may include nanocomposites, multilayered oxide materials, or superlattices. A nanostructure may include a plurality of oxide layers where at least one layer includes a TMO. The layers that do not include a transition metal may be referred to as a non-MIT layer. Using nanocomposites or multilayed oxide materials can increase the area of internal interfaces to enhance the phonon-boundary scattering, and therefore increase the thermal resistance (decrease the thermal conductance). From a dimensionality point of view, nanocomposites may be 3D nanostructures that confine phonon transport in all the directions, while multilayer or superlattice structures may be 2D nanostructures that confine phonon transport in one dimension—in the normal direction to the films. The metal oxide nanostructures can be fabricated as nanocrystalline or amorphous forms, thus making lattice match conditions in single crystal growth less applicable, generally. Therefore, a variety of oxide materials may be used in the non-MIT layers for an artificial nanostructure. Non-MIT layers may include oxide materials with a relatively small thermal conductivity for a non-MIT. The non-MIT may have a thermal conductivity less than the TMO to enhance the MIT mechanism at lower currents. Metals, alloys, and oxide materials with low thermal conductivity can be found in various material databases.

For example, when using two oxide materials to form the nanostructure 612, a first material, referred to as “core” in a core layer 616, may show MIT at a certain transition temperature, and second material, referred to as “matrix” in a matrix layer 614, may have a small thermal conductivity. The matrix may not react with the core material to form other intermediate phases or alloys, which can deteriorate the MIT behavior of the core material. The thermodynamic guideline to determine the compatibility of oxides from the free energies of formation perspective can be the Ellingham diagrams. The matrix oxide materials can be positioned lower than the core material in the Ellingham diagrams, which can mean the matrix oxide can be thermodynamically more stable than the core oxide. Electronic properties of the core and matrix materials can be chosen so that the matrix acts as an insulator or semiconductor near the operational temperature, while the core may have a MIT. The core layer may include a TMO and the matrix layer or matrix oxide layer may include an oxide with a formation free energy less than the formation free energy of the TMO.

For example, if Ti₄O₇ is used in the core layer 616, TiO₂ may be used in the matrix layer 614 to form a TiO₂/Ti₄O₇ system nanostructure. The TiO₂ matrix layer can have a thermal conductivity (κ) less than the Ti₄O₇ core layer. The thermal conductivity for TiO₂ can be 11.7 W/(m·K) at 25° C. and 6.69 W/(m·K) at 100° C. In a V₂O₅/VO₂ system nanostructure, VO₂ can be used in the core layer and V₂O₅ can be used in the matrix layer.

The nanostructure 612 (FIG. 7B) or the metal oxide structure 610 (FIG. 7A) may have a thickness greater than a few nanometers and less than 300 nanometers. The overall device active layer of the nanostructure 612 or the metal oxide structure can be less than 200 nm and the overall thickness of the oxide layer may be less than 100 nm The layer thickness for the nanostructure may be greater than one angstrom or less than 100 nanometers.

The oxide nanostructure may be fabricated using physical and chemical deposition processes for oxide materials (e.g., DC and RF sputtering of oxide targets). Reactive sputtering of metal targets may be used. Thermal and electron-beam evaporation, pulsed-laser deposition, atomic layer deposition, and various form of chemical vapor deposition (e.g., MOCVD, PECVD, LPCVD) may also be used in the fabrication of oxide nanostructures.

The insulating sheath 620 may provide an electrically insulating sheath of the nanostructure 612 or the metal oxide structure. The insulating sheath may have relatively low thermal conductivity for an insulator. The insulating sheath may include silicon dioxide (SiO₂), silicon nitride (Si₃N₄) and ternary variants, spin-on glasses (e.g., HSQ), Nitrogen (N₂), air, vacuum, or combination thereof. SiO₂ may have a thermal conductivity (κ) less than 1 W/(m·K) for temperature range between 25° C. and 127° C. N₂ or air may have a thermal conductivity (κ) approximately 0.025 W/(m·K) for temperature range between 25° C. and 127° C. Other semiconductor process materials with electrically insulating properties and a low thermal conductivity may also be used.

As illustrated in FIG. 7C, the TMO MIM device 600 may include a memristive device 630 adjacent to the metal oxide structure 610 or within the metal oxide structure (not shown) between the first electrode and second electrode. The TMO MIM device may be in series with a memristive device 632 or an electrode 608 of the TMO MIM device may be adjacent to the memristive device, as illustrated in FIG. 7D.

Another example provides a fabricating a semiconductor device for providing heat management. The method may include the operation of providing a substrate. The operation of depositing a first conductive layer with a low thermal conductivity on the substrate may follow. The next operation of the method may be etching the first conductive layer selectively forming a first electrode. The method may further include depositing a metal oxide layer on the first electrode. The metal oxide layer may include a transition metal oxide (TMO). The operation of etching the metal oxide layer to form a metal oxide structure and to reduce the junction area of the metal oxide layer with the first electrode may follow. The next operation of the method may be depositing an electrically insulating layer surrounding the metal oxide structure. The method may further include etching the electrically insulating layer to expose the metal oxide structure. The operation of depositing a second conductive layer with a low thermal conductivity on the electrically insulating sheath and metal oxide structure may follow. The next operation of the method may be etching the second conductive layer selectively forming a second electrode.

While the forgoing examples are illustrative of the principles of the present disclosure in one or more particular applications, it will be apparent to those of ordinary skill in the art that numerous modifications in form, usage and details of implementation can be made without the exercise of inventive faculty, and without departing from the principles and concepts described. Accordingly, it is not intended that the invention be limited, except as by the claims set forth below.

What is claimed is:

1. A semiconductor device for providing heat management, comprising:
a first electrode with low metal thermal conductivity;
a second electrode with low metal thermal conductivity;
a metal oxide structure including a transition metal oxide (TMO) electrically coupled to the first electrode and second electrode, and the metal oxide structure being disposed between the first electrode and second electrode; and
an electrically insulating sheath with low thermal conductivity surrounding the metal oxide structure.

2. The semiconductor device of claim 1, wherein the metal oxide structure exhibits first order metal-insulator phase transition (MIT) characteristics in a pre-defined temperature range.

3. The semiconductor device of claim 1, wherein the metal oxide structure exhibits a current controlled (CC) negative differential resistance (NDR) current-voltage (I-V) characteristics in a pre-defined temperature range.

4. The semiconductor device of claim 1, wherein a transition metal in the transition metal oxide (TMO) is selected from the group consisting of elements from the third group, fourth group, fifth group, sixth group, seventh group on the periodic table, and combination thereof.

5. The semiconductor device of claim 1, wherein a transition metal in the transition metal oxide (TMO) is selected from the group consisting of Vanadium (V), Titanium (Ti), Niobium (Nb), Tantalum (Ta), Manganese (Mn), Hafnium (Hf), Molybdenum (Mo), Tungsten (W), Chromium (Cr), Zirconium (Zr), Scandium (Sc), Yttrium (Y), Lanthanum (La), Rhenium (Re), Technetium (Tc), and combination thereof.

6. The semiconductor device of claim 1, wherein the metal oxide structure includes the transition metal oxide (TMO) selected from the group consisting of Vanadium (IV) oxide (VO₂), Titanium Magneli phase (Ti₄O₇), NbO₂, NiO, Ti₂O₃, MoO₃—TeO₂, and combination thereof.

7. The semiconductor device of claim 1, wherein a thermal conductivity (κ) of the first electrode and the second electrode is less than 100 W/(m·K).

8. The semiconductor device of claim 1, wherein a junction area diameter of the metal oxide with the first electrode and the second electrode is greater than 1 nanometer and less than 100 nanometers.

9. The semiconductor device of claim 1, wherein the first electrode and the second electrode is selected from the group consisting of a refractory metal nitrides, refractory metal silicides, electrically doped polycrystalline semiconductors, and their combined intermediate phases.

10. The semiconductor device of claim 1, wherein the first electrode and the second electrode is selected from the group consisting of TiN, TaN, Ta₂N, WN₂, NbN, MoN, TiSi₂, TiSi, Ti₅Si₃, TaSi₂, WSi₂, NbSi₂, V₃Si, electrically doped Si polycrystalline, electrically doped Ge polycrystalline, and combination thereof.

11. The semiconductor device of claim 1, wherein electrically insulating sheath includes silicon dioxide (SiO₂), silicon nitride (Si₃N₄) and ternary variants, spin-on glasses, or Nitrogen (N₂) surrounding the metal oxide structure.

12. The semiconductor device of claim 1, wherein the metal oxide structure includes a memristive device.

13. A semiconductor device for providing heat management, comprising:
a first electrode including a with a metal layer with high metal thermal conductivity disposed on a conductive layer with low metal thermal conductivity;
a second electrode including a with a metal layer with high metal thermal conductivity disposed on a conductive layer with low metal thermal conductivity;
a metal oxide structure including a transition metal oxide (TMO) electrically coupled to the first electrode and second electrode, and the metal oxide structure being disposed between the conductive layer of the first electrode and the conductive layer of the second electrode, and the conductive layers are in closer proximity to the metal oxide structure than the metal layers; and
an electrically insulating sheath with low thermal conductivity surrounding the metal oxide structure.

14. The semiconductor device of claim 13, wherein a thermal conductivity (κ) of the metal layer of the first electrode and the second electrode is greater than 175 W/(m·K).

15. A semiconductor device for providing nanoscale heat management, comprising:
a first electrode with low metal thermal conductivity;
a second electrode with low metal thermal conductivity; and
a nanostructure with a plurality of oxide layers electrically coupled to the first electrode and second electrode and disposed between the first electrode and second electrode, wherein at least one layer includes a transition metal oxide (TMO).

16. The semiconductor device of claim 15, further comprising an electrically insulating sheath with low thermal conductivity surrounding the nanostructure.

17. The semiconductor device of claim 15, wherein the nanostructure includes a matrix oxide layer and a core oxide layer, and the core oxide layer includes the transition metal oxide (TMO), and the matrix oxide layer includes an oxide with a formation free energy less than the formation free energy of the transition metal oxide (TMO).

18. The semiconductor device of claim 15, wherein the nanostructure includes a matrix oxide layer and a core oxide layer, and the core oxide layer includes the transition metal oxide (TMO), and the matrix oxide layer has a conductivity less than the transition metal oxide (TMO).

19. The semiconductor device of claim 15, wherein a layer thickness of at least one oxide layer is greater than one angstrom and less than 100 nanometers.

20. The semiconductor device of claim 15, wherein a device thickness of the nanostructure is greater than 10 nanometers and less than 300 nanometers.
